(19) United States
(12) Patent Application Publication
(10) Pub. No.: US 2010/0237307 A1
(43) Pub. Date: Sep. 23, 2010

(54) Modular solar fence system

(76) Inventors: Mark Milburn, Missoula, MT (US); John W. Coombes, Wlsa, MT (US)

Correspondence Address: BAMBI FAIVRE WALTERS, PC, PO BOX 5743, WILLIAMSBURG, VA, 23188, US

(21) Appl. No.: 12/383,238

(22) Filed: Mar. 20, 2009

(51) Int. Cl. E04H 17/00; E04H 17/16; E04H 17/08; H01L 31/042; H01L 31/00

(52) U.S. Cl. 256/1; 256/34; 256/19; 136/244; 136/252

(57) ABSTRACT

Exemplary embodiments include a solar and non-solar fence slat designs for use in a modular fence system. The fence slat comprises an elongated slat body having a front side wall, a back side wall, bottom side wall, top side wall, right side wall and left side wall. The slat first and second fasteners coupled to right and left sides of the elongated slat body and being configured to couple or interlock with adjacent slats. The slat also includes at least one chain-link interface coupler coupled to the back side wall to connect to at least one horizontal cross-bar of a chain-link fence. In an embodiment, the fence slat has a solar panel integrated therewith.

### NOTICE OF COPYRIGHT PROTECTION

A portion of the disclosure of this patent document and its figures contain material subject to copyright protection. The copyright owner has no objection to the facsimile reproduction by anyone of the patent document or the patent disclosure, but otherwise reserves all copyrights whatsoever.

### BACKGROUND

I. Field

The invention relates to modular fences.

II. Background

Chain link fences do not provide privacy between neighbors. Thus, privacy fences have become very popular, including both wood and synthetic types. Privacy fences of the wood type require fence posts to be installed and top and bottom horizontal cross-bars. Vertical slats are individually nailed to these top and bottom cross-bars. The installation is time consuming as care is taken to ensure all of the vertical slats are horizontally aligned. Thus, most individuals hire a company to install the wood privacy fence.

Synthetic fences exhibit superior durability and have low maintenance. Synthetic fences retain their color and do not decay unlike natural wood fences. When a privacy fence is installed, in place of a chain-link fence, the chain-link fence is torn down and discarded. Like wood privacy fences, synthetic-type privacy fences also require fence posts to be installed and do not utilize existing chain-link fence support systems even though the chain-link fence is made of a durable and strong metal.

As the cost of energy increases, people are diligently trying to find alternative economical energy sources. Sunlight is such a source. However, providing solar panels in an attractive and economical manner is often a challenge so that the homeowner is not distracted by large solar panels.

### SUMMARY

The aforementioned problems, and other problems, are reduced, according to exemplary embodiments, by the solar fence slats, non-solar fence slats, modular fence systems and methods for generating electricity from sunlight using solar panels incorporated into a privacy fence.

According to an exemplary embodiment, a fence slat comprises an elongated slat body having a front side wall, a back side wall, bottom side wall, top side wall, right side wall and left side wall. The slat first and second fasteners coupled to right and left sides of the elongated slat body and being configured to couple or interlock with adjacent slats. The slat also includes at least one chain-link interface coupler coupled to the back side wall to connect to at least one horizontal cross-bar of a chain-link fence.

In one embodiment, the elongated slat body has a solar panel integrated therewith.

According to another exemplary embodiment, a modular fence system is provided. The fence system includes a plurality of fence slats configured to connect to at least one horizontal cross-bar of a chain-link fence or other support system. One or more of the fence slats may include solar panels.

Other systems, methods, and/or products according to embodiments will be or become apparent to one with skill in the art upon review of the following drawings, and further description. It is intended that all such additional systems, methods, and/or products be included within this description, be within the scope of the present invention, and be protected by the accompanying claims.

### BRIEF DESCRIPTION OF THE DRAWINGS

The above and other exemplary embodiments, objects, uses, advantages, and novel features are more clearly understood by reference to the following description taken in connection with the accompanying figures wherein:

FIG. 1 illustrates a perspective view of a front side of a solar fence slat in accordance with some of the exemplary embodiments;

FIG. 2 illustrates a perspective view of a back side of the solar fence slat in accordance with the embodiment of FIG. 1;

FIG. 3 illustrates a side view of the solar fence slat in accordance with the embodiment of FIG. 1;

FIG. 4 illustrates the bottom view of the solar fence slat in accordance with the embodiment of FIG. 1;

FIG. 5 illustrates a cross-sectional view of a solar fence slat in accordance with some of the exemplary embodiments;

FIG. 6 illustrates a cross-sectional view of a non-solar fence slat in accordance with some of the embodiments;

FIG. 7 illustrates a perspective view of a front side of a modular solar fence system in accordance with some of the exemplary embodiments;

FIG. 8 illustrates a perspective view of a back side of the modular solar fence system in accordance with some of the exemplary embodiments;

FIG. 9 illustrates a partial view of a side of another solar fence slat in accordance with some exemplary embodiments;

FIG. 10 illustrates a partial view of a side of yet another solar fence slat in accordance with some exemplary embodiments;

FIG. 11A illustrates a perspective view of yet another solar fence slat with a illumination device in accordance with some of the exemplary embodiments;

FIG. 11B illustrates a cross-sectional view of another solar fence slat in accordance with some of the embodiments;

FIG. 12 illustrates a front side of yet another solar fence slat in accordance with some of the exemplary embodiments;

FIG. 13 illustrates a side view of parallel and overlapping solar fence slats installed in accordance with some of the exemplary embodiments; and

FIG. 14 illustrates a bottom view of a yet another solar fence slat of FIG. 13.

### DESCRIPTION

The word “exemplary” is used herein to mean “serving as an example, instance, or illustration.” Any configuration or design described herein as “exemplary” is not necessarily to be construed as preferred or advantageous over other configurations or designs.

This invention now will be described more fully hereinafter with reference to the accompanying drawings, in which exemplary embodiments are shown. This invention may, however, be embodied in many different forms and should not be construed as limited to the embodiments set forth herein. These embodiments are provided so that this disclosure will be thorough and complete and will fully convey the scope of the invention to those of ordinary skill in the art. Moreover, all statements herein reciting embodiments of the invention, as well as specific examples thereof, are intended to encompass both structural and functional equivalents thereof. Additionally, it is intended that such equivalents include both currently known equivalents as well as equivalents developed in the future (i.e., any elements developed that perform the same function, regardless of structure).

Thus, for example, it will be appreciated by those of ordinary skill in the art that the diagrams, schematics, illustrations, and the like represent conceptual views or perspective views illustrating some of the solar fence slats, fence system and methods embodying this invention. The functions of the various elements shown in the figures may be provided through the use of dedicated hardware that may vary in shape, attachment, size, and other physical features. Those of ordinary skill in the art further understand that the exemplary solar fence slats, module fence systems, and/or methods described herein are for illustrative purposes and, thus, are not intended to be limited to any particular named manufacturer or other relevant physical limitation (e.g., color of the slat).

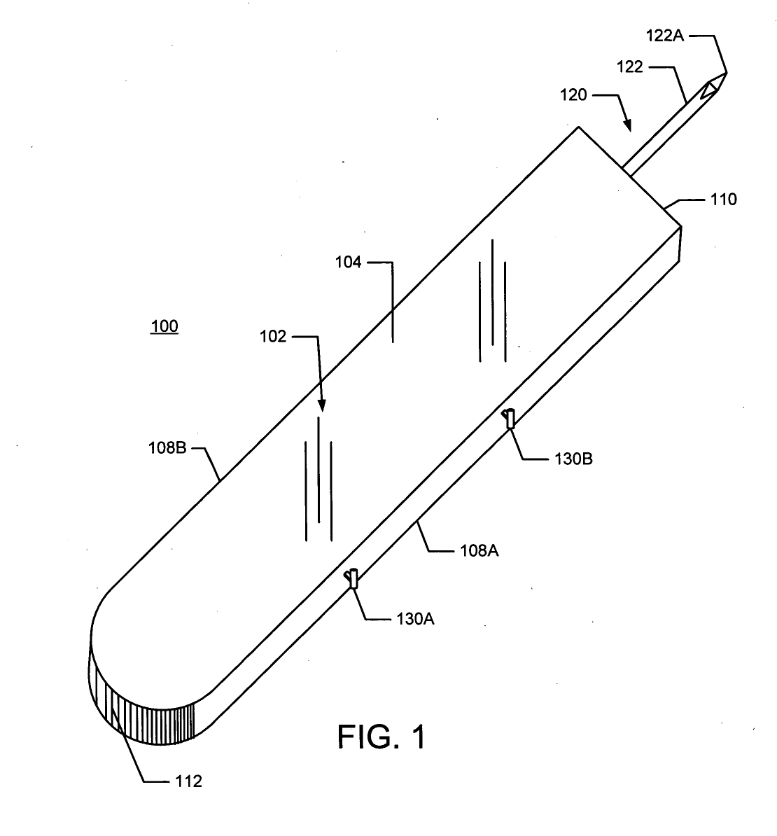

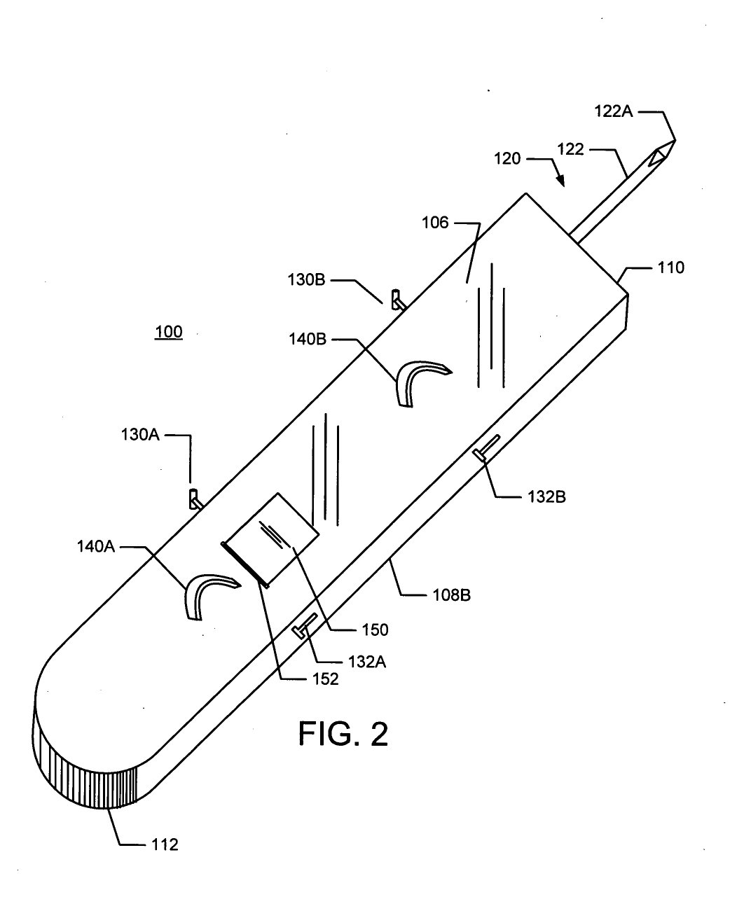

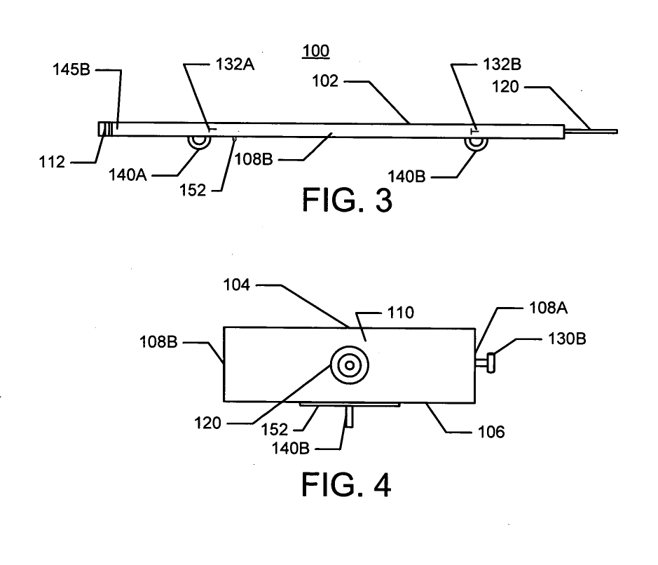

FIGS. 1 and 2 illustrate a perspective view of a front side and a back side, respectively, of a solar fence slat 100. The solar fence slat 100 includes an elongated body member 102 configured as a privacy fence slat. The elongated body member 102, in an embodiment, has a hollow interior. The elongated body member 102 includes a front side wall 104, a back side wall 106, right and left side walls 108A and 108B, and bottom side wall 110. A top side of the elongated body member includes a solar panel 112. The front side wall 104, back side wall 106, right and left side walls 108A and 108B, bottom side wall 110 and solar panel 112 together from a hollow quasi-rectangular structure. The front side wall 104, back side wall 106, right and left side walls 108A and 108B, and bottom side wall 110 are linear and straight. For example, the front side wall 104 and back side wall 106 are parallel and overlap. The right and left side walls 108A and 108B are parallel and overlap and are coupled perpendicular to longitudinal sides of the front side wall 104 and back side wall 106. The bottom side wall 110 is coupled perpendicularly to a bottom edge of the front side wall 104 and back side wall 106, as best seen in FIG. 4. The solar panel 112, in an embodiment, is curved or arch-shaped. Nonetheless, the solar panel 112 may have other shapes. For example, in lieu of a curved or arch-shaped, the solar panel 112 may be straight and linear such that the solar panel 112 is parallel with the bottom side wall 110. Other configurations of the top side wall 112 will be described in detail later.

The elongated body member 102 of the solar fence slat 100 is constructed of synthetic materials such as plastic, vinyl, polyvinyl chloride (PVC) or other synthetic materials. The elongated body member 102 may be made of man-made material, natural material or a combination thereof. In an embodiment, the slats 100 may be five (5), six (6) or seven (7) feet tall.

The exterior surfaces of one or more of the front side wall 104, the back side wall 106, the right and left side walls 108A and 108B, and the bottom side wall 110 have embedded or embossed in the exterior surface thereof a wood grain pattern. The wood pattern may provide texture to the exterior surfaces to provide a faux-wood appearance. Nonetheless, the exterior surface may be smooth with a satin, semi-gloss or high-gloss finish. In an embodiment, the exterior surface may be white or other neutral colors adapted to be painted. In an embodiment, the exterior surface may be available in a variety of colors.

The bottom side wall 10 has coupled thereto a spike or stake 120. The spike or stake 120 includes an elongated portion 122 and, in an embodiment, a pointed tip 122A. The spike or stake 120 is received in the ground or earth so as to stabilize the solar fence slat 100.

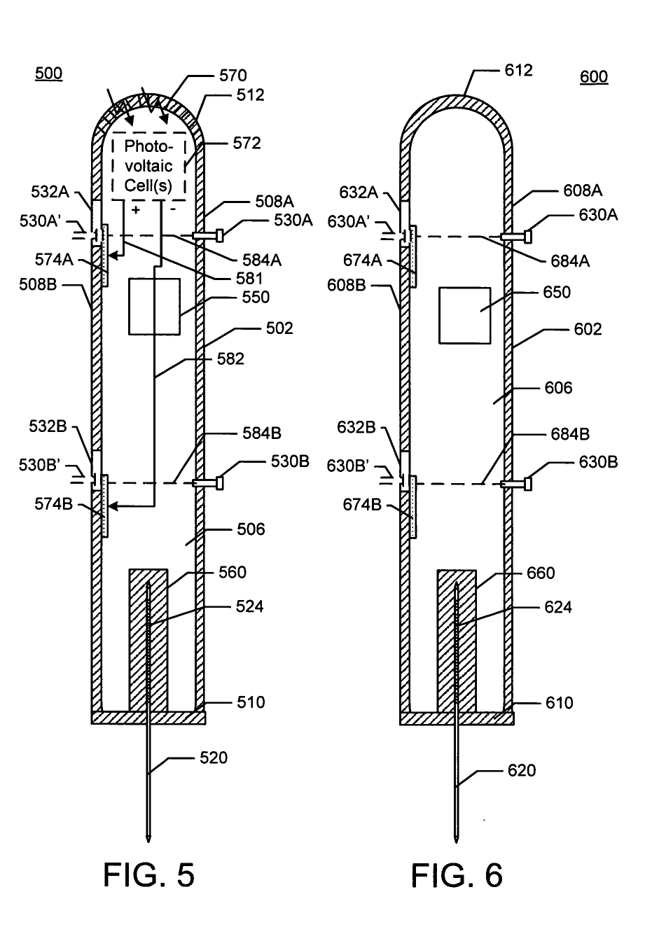

The right side wall 108A includes fasteners 130A and 130B. The left side wall 108B includes fasteners 132A and 132B which interlock, mate with, fasten to or, otherwise, couple to fasteners 130A and 130B, respectively, of an adjacent fence slat. In an embodiment, the mated fasteners 130A and 132A are configured to be electrically coupled to each other so that a current, electrical charge or voltage can be communicated between adjacent slats, as will be described in more detail in relation to FIG. 5.

In an embodiment, the fasteners 130A and 132A and/or fasteners 130B and 132B are paired fasteners that make up a modese fastening system. The modese fastening system includes a male modese clip (i.e., fasteners 130A and 130B) and a female modese slide (i.e., fasteners 132A and 132B). Nonetheless, other fastening systems may be used.

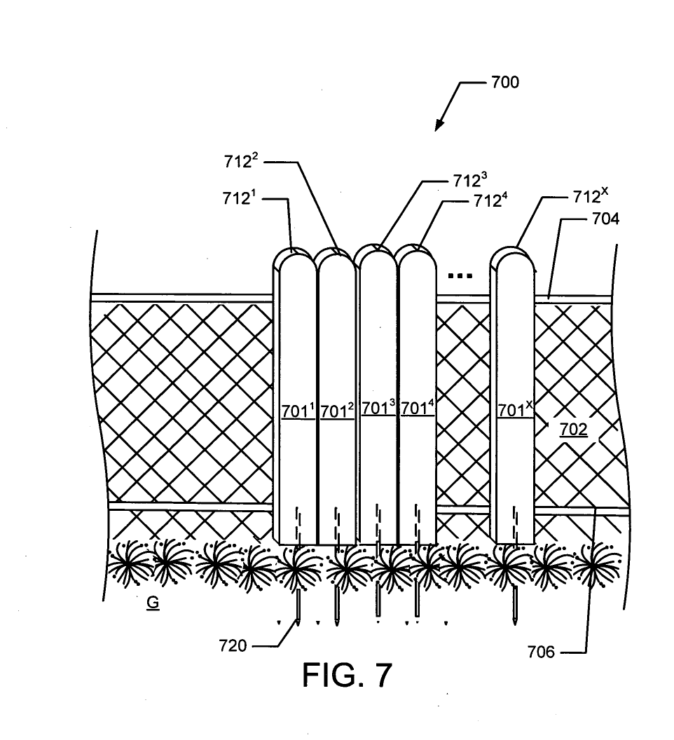

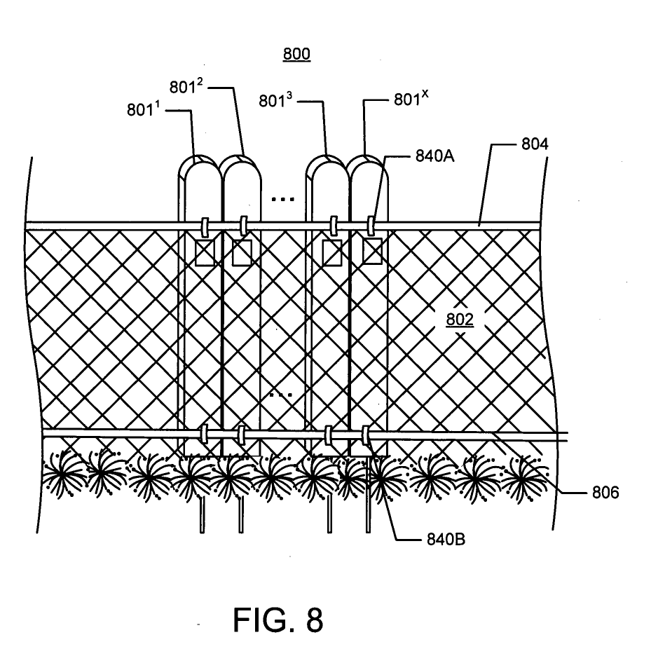

The back side wall 106 includes at least one chain-link interface 140A, also shown in FIG. 3. The chain-link interface 140A includes a mechanism to affix the solar fence slat 100 to a chain-link fence (FIG. 7 or 8). In the exemplary embodiment, the chain-link interface 140A is configured to receive therein, affix to, clip or clamp to a top horizontal cross-bar of a chain-link fence. In the exemplary embodiment, two chain-link interfaces 140A and 140B are provided. The chain-link interface 140B is positioned in proximity to a bottom end of the slat 100 and is configured to receive therein, affix to, clip or clamp to a bottom horizontal cross-bar of a chain-link fence.

The chain-link interface 140A or 140B may have various configurations. In one configuration, the chain-link interface 140A or 140B may be semi-circular and oriented to cradle therein an underside of the horizontal cross-bars. The chain-link interface 140A or 140B may be semi-circular and oriented to clip or clamp over a top side of the horizontal cross-bars. Nonetheless, the chain-link interface 140A or 140B may be removable from the slat 100 similar to a bracket.

The back side wall 106 further includes an access panel 150 to provide access to the interior of the elongated body member 102. In an embodiment, the access panel 150 is hingedly coupled to the back side wall 106 via hinge member 152. The access panel 150 closes an aperture (not shown) formed in the back side wall 106. In an embodiment, the access panel 150 and aperture (not shown) is positioned below the (top) chain-link interface 140A so that when the slat 100 is installed, the access panel 150 is not accessible. Nonetheless, the access panel 150 and aperture (not shown) may be placed elsewhere on the back side wall 106.

FIG. 5 illustrates a cross-sectional view of a solar fence slat 500. The solar fence slat 500 has the same construction as the solar fence slat 100. The interior of the solar fence slat 500 is essentially hollow. The elongated body member 502 has the front side wall removed. The elongated body member 502 includes back side wall 506, right and left side walls 508A and 508B, bottom side wall 510 and solar panel 512. The solar panel 512, in an embodiment, is curved or arch-shaped. The back side wall 506 includes an access panel 550.

The bottom side wall 510 has a spike or stake support 560 coupled thereto. In an embodiment, the spike or stake support 560 has threaded therein a threaded end 524 of the spike or stake 520. The support 560 provides vertical support for the spike or stake 520 used to anchor the slat 500. The spike or stake 520 can be lengthened or shortened by turning the spike or stake 520 in a first direction (i.e., clockwise) or a second direction (i.e., counterclockwise).

In an embodiment, a lower end of the solar fence slat 500 is configured to be cut so that a length of the solar fence slat 500 can be shortened. In this embodiment, the bottom side wall 510 may be removably coupled or made longer so that as the bottom end of the solar fence slat 500 is shortened, by cutting, the bottom end can be closed. The bottom side wall 510, if removable can be re-attached to close the bottom end.

As previously described the spike or stake 520 can be lengthened or shortened to vary the height of the slat 500. The spike or stake 520 is approximately 36 inches long. Nonetheless other lengths can be used. In an embodiment, the threaded end 524 may be 30 inches and the spike or stake 520 may be 6 inches. Varying the length of the spike or stake 520 (that portion that is exterior to bottom side wall 510) allows the fence height to be adjusted vertically, as will be described in more detail in relation to FIG. 7.

The solar panel 512 comprises, in an embodiment, a glass substrate 570 or other protective barrier, denoted by hatched lines, and photovoltaic cell(s) 572 covered by the glass substrate 570. The photo-voltaic cell(s) 572 converts sunlight into electricity. The photo-voltaic cell(s) 572 are electrically coupled to electrical connecting pads 574A and 574B adjacent to fasteners 532A and 532B, respectively via electrical wires 581 and 582, respectively. The fasteners 530A and 530B are electrically coupled to electrical connecting pads 574A and 574B, respectively via and electrical wires 584A and 584B, respectively.

The right side wall 508A includes fasteners 530A and 530B. The left side wall 508B includes fasteners 532A and 532B which interlock, mate with, fasten to or, otherwise, couple to fasteners 530A′ and 530B′ (shown in phantom), respectively, of an adjacent fence slat. The fasteners 530A′ and 530B′ (shown in phantom) when mated or interlocked with fasteners 532A and 532B, respectively, are in electrical contact. Thus, electrical charge (+,−) is capable of being communicated between the solar panel slats 500 to a remote solar battery, electrical system of the home, or other devices requiring electrical power. The fasteners 530A and 530B may be plugs while fasteners 532A and 532B may include jacks that electrically connect to and friction-fit couple with fasteners 530A and 530B. Thus, the fasteners 530A and 530B and fasteners 532A and 532B are made of electrically conductive material.

The electrical connecting pads 574A and 574B may include a circuit board.

FIG. 6 illustrates a cross-sectional view of non-solar fence slat 600. The non-solar fence slat 600 has a similar construction as the solar fence slat 100 and 500 but does not have a solar panel. The interior of the solar fence slat 600 is essentially hollow. The elongated body member 602 has the front side wall removed. The elongated body member 602 includes back side wall 606, right and left side walls 608A and 608B, bottom side wall 610 and top side wall 612. The top side wall 612, in an embodiment, is curved or arch-shaped. Nevertheless, the top side wall 612 may have other shapes. The back side wall 606 includes access panel 650.

The bottom side wall 610 has a spike or stake support 660 coupled thereto. In an embodiment, the spike or stake support 660 has threaded therein a threaded end 624 of the spike or stake 620. The support 660 provides vertical support for the spike or stake 620 used to anchor the slat 600. The spike or stake 620 can be lengthened or shortened by turning the spike or stake 620 in a first direction (i.e., clockwise) or a second direction (i.e., counterclockwise).

As previously described, the spike or stake 620 can be lengthened or shortened to vary the height of the slat 600.

The right side wall 608A includes fasteners 630A and 630B. The left side wall 608B includes fasteners 632A and 632B which interlock, mate with, fasten to or, otherwise, couple to fasteners 630A′ and 630B′ (shown in phantom), respectively, of an adjacent fence slat. The fasteners 630A′ and 630B′ (shown in phantom) when mated or interlocked with fasteners 632A and 632B, respectively, are in electrical contact. Thus, electrical charge is capable of being communicated between the solar panel slats 500 and/or 600 to a remote rechargeable battery, electrical system of the home, or other devices requiring electrical power. The fasteners 630A and 630B may be plugs while fasteners 632A and 632B may include jacks that electrically connect to and friction-fit couple with fasteners 630A and 630B. Thus, the fasteners 630A and 630B and fasteners 632A and 632B are made of electrically conductive material.

The fasteners 630A and 630B are electrically coupled to electrical connecting pads 674A and 674B adjacent to fasteners 632A and 632B, respectively via electrical wires 584A and 584B, respectively. Although, the non-solar fence slat 600 does not collect solar energy, the electrical energy is still communicated or propagated along a length of the fence system to a remote rechargeable battery, electrical system of the home, or other devices requiring electrical power.

FIG. 7 illustrates a perspective view of a front side of a modular solar fence (MSF) system 700. The MSF system 700 includes a plurality of fence slats 701¹, 701², 701³, 701⁴, . . . , 701^{X} configured to be interlocked or interconnected together to form a privacy fence using an existing chain-link fence (CLF) system 702 for support. Each of the plurality of fence slats 701¹, 701², 701³, 701⁴, . . . , 701^{X} are configured to be clipped, clamped or otherwise attached to the horizontal cross bars 704 and 706 of the CLF system 702. In the exemplary configuration, the length of each fence slat of the plurality of fence slats 701¹, 701², 701³, 701⁴, . . . , 701^{X} extends above the height of the highest height of the CLF system 702. The MSF system 700 is configured to be installed directly in front or back of the existing CLF system 702.

In one embodiment, all of the fence slats of the plurality of fence slats 701¹, 701², 701³, 701⁴, . . . , 701^{X} are solar fence slats (e.g. 100 and 500). Each of the plurality of fence slats 701¹, 701², 701³, 701⁴, . . . , 701^{X} includes a solar panel 712¹, 712², 712³, 712⁴, . . . , 712^{X} to convert the sunlight into electricity. Thus, the MSF system 700 produces an amount of electricity that can be stored in a remote battery or used by a residence or other electrically powered device.

In another embodiment, the plurality of fence slats 701¹, 701², 701³, 701⁴, . . . , 701^{X} include a combination of solar fence slats 100 or 500 and non-solar fence slats 600. The ratio of solar fence slats 100 or 500 and non-solar fence slats 600 may be a function of the amount of electricity desired. An increase in solar fence slats increases the surface area of the solar panels to convert the sunlight into electricity. Thus, the more solar fence slats in the MSF system 700, the more electricity generated by the MSF system 700.

The heights of the solar fence slats 100 or 500 and the non-solar fence slats 600 of the MSF system 700 may be varied to create a wave pattern by turning the spike or stake 720 in a first direction (i.e., clockwise) or a second direction (i.e., counterclockwise). The heights of adjacent slat may be varied such that odd numbered slats have the same height while even numbered slats have the same height but different from the height of the odd numbered slats. Additionally, the heights of the slats may be adjusted to compensate for terrain variations.

FIG. 8 illustrates a perspective view of a back side of the MSF system 800. The MSF system 800 includes a plurality of fence slats 801¹, 801², 801³, . . . , 801^{X} configured to be interlocked or interconnected together to form a privacy fence using an existing chain-link fence (CLF) system 802 for support. Each of the plurality of fence slats 801¹, 801², 801³, . . . , 801^{X} are configured to be clipped, clamped or otherwise attached to the horizontal cross bars 804 and 806 of the CLF system 802 via chain-link interfaces 840A or 840B, respectively, of each slat.

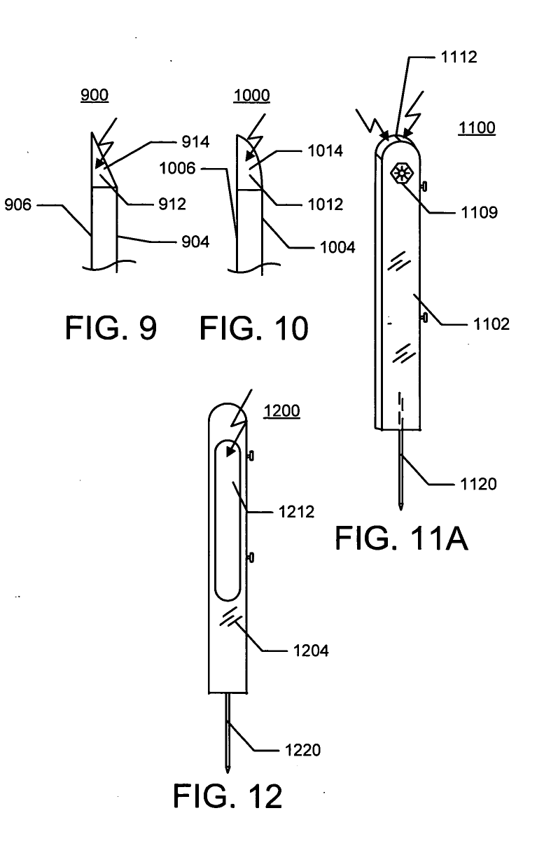

FIG. 9 illustrates a partial view of a side of another solar fence slat 900. The solar fence slat 900 includes a triangularly-shaped solar panel 912. In this embodiment, the surface area defined by a side 914 corresponds to a hypotenuse side of the solar panel 912. The side 914 is shown facing the front side wall 904. Nonetheless, the side 914 may alternately face the back side wall 906. The amount of surface area is a function of the length of the hypotenuse side. Thus, the width and length of the solar panel 912 may be larger than the solar panel 112 or 512. The arrow indicates the direction the sunlight is received by the solar panel 912.

FIG. 10 illustrates a partial view of a side of yet another solar fence slat 1000. The solar fence slat 1000 includes a dome-shaped solar panel 1012. In this embodiment, the surface area defined by a side 1014 corresponds to a hypotenuse side of the solar panel 1012. However, instead of a flat and linear surface as in FIG. 9, the side 1014 is convex similar to a convex lens. The side 1014 is shown facing the front side wall 1004. Thus, in this embodiment, part of the solar panel 1012 utilizes some of the surface area of the front side wall 1004. Nonetheless, the side 1014 may alternately face the back side wall 1006. The arrow indicates the direction the sunlight is received by the solar panel 1012.

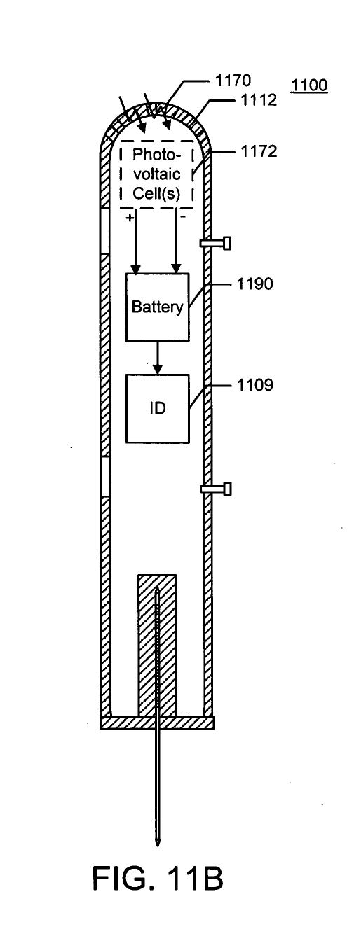

FIGS. 11A and 11B illustrate a perspective view and a cross-sectional view of yet another solar fence slat 1100 with an illumination device (ID) 1109. The solar fence slat 1100 is similar to the solar fence slat 500 but also includes a solar battery 1190 coupled to photo-voltaic cell(s) 1172 of the solar panel 1112. The photo-voltaic cell(s) 1172 are protected by a glass substrate 1170 or other protective barrier. The ID 1109 is included to provide perimeter lighting. The ID 1109 is shown coupled to the rechargeable battery 1190. The ID 1109 may be directly or indirectly coupled to the photo-voltaic cell(s) 1172.

Additionally, in this embodiment, electrical wiring is optional (not shown). Thus, the electricity created by the photo-voltaic cell(s) 1172 is not electrically communicated to adjacent slats. The battery 1190 is used to store electricity so that the ID 1109 illuminates after dusk and before dawn or when there is little or no sunlight. The ID 1109 may be provided with a sensor to control the illumination of the ID 1109 to only illuminate after dusk and before dawn or when there is little or no sunlight. Slat 1100 is a solar-power perimeter lighting fence slat. The slat 1100 may be incorporated in to a MSF system with only slats 1100 and a combination of slats 1100 and non-solar fence slats 600.

Slat 1100 may be provided with electrical wiring described above in relation to FIGS. 5 and 6. In this configuration, the slat 1100 may be used as part of a complimentary slat for designing the MSF system 700 that communicates electricity through all slat of the MSF system 700.

FIG. 12 illustrates a front side of yet another solar fence slat 1200. In the exemplary embodiment, slat 1200 has an elongated solar panel 1212 positioned along the front side wall 1204. The arrow indicates at least one direction the solar panel 1212 would collect sunlight. The elongated solar panel 1212 increases the surface area capable of collecting sunlight.

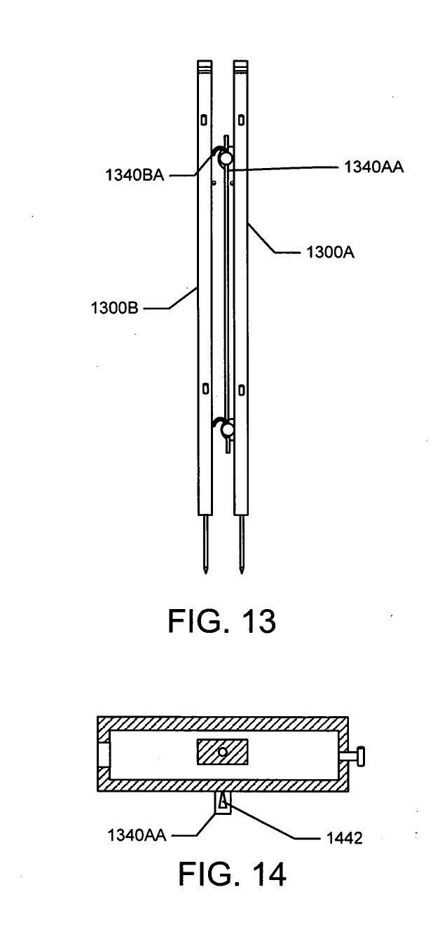

FIG. 13 illustrates a side view of parallel and overlapping solar fence slats 1300A and 1300B. The solar fence slat 1300A may be constructed as any one of slats 100, 500, 600 or 1100. However, solar fence slat 1300A and 1300B are installed on opposite sides of a chain-link fence. In the exemplary embodiment, slat 1300B has at least one hook-shaped chain-link interface 1340BA. However, slat 1300A includes chain-link interface 1340AA which is similar to interfaces 140A and 140B described above in relation to FIG. 1. However, interface 1340AA has a notch 1442 formed therein, as best seen in FIG. 14. The notch 1442 is used to receive or hook with the hook-shaped chain-link interface 1340BA.

In view of the foregoing, homeowners with existing chain-link fences can cover obscure them with an attractive MSF system or non-solar fence system. The MSF system is sturdy when installed by the use of an existing chain-link fence system. The solar fence slats and the solar panels may have different physical configurations and the invention envisions accommodating these various configurations and designs. Likewise, the non-solar fence slat may have different physical configurations.

In an embodiment, a fence slat 100, 500, 600, 1100, 1300A or 1300B includes an elongated slat body having a front side wall, a back side wall, bottom side wall, top side wall, right side wall and left side wall. The fence slat includes first and second fasteners coupled to right and left sides of the elongated slat body and being configured to couple or interlock with adjacent slats. The fence slat also includes at least one chain-link interface coupler coupled to the back side wall to connect to a horizontal cross-bar of a chain-link fence.

In one embodiment, the fence slat is a non-solar fence slat used to create a privacy fence. In another embodiment, the fence slat is a solar fence slat used to create a privacy fence wherein the solar fence slat has integrated in the elongated slat body a solar panel.

In an embodiment, configurations of the fence slat described above are used to create non-solar, solar or other modular customized privacy fence system utilizing an existing chain-link fence system to support the fence slats.

In an embodiment, if an existing chain-link fence is not available to support the fence slats, a support system of vertical and horizontal metal support posts (similar to those used in a chain-link fence system) may be installed for use with the modular privacy fence system described herein.

In an embodiment, if an existing chain-link fence is not available to support the fence slats, a support system of vertical and horizontal synthetic (e.g. PVC) support posts may be installed for use with the modular privacy fence system described herein.

While the present invention has been described with respect to various features, aspects, and embodiments, those skilled and unskilled in the art will recognize the invention is not so limited. Other variations, modifications, and alternative embodiments may be made without departing from the spirit and scope of the present invention.

What is claimed is:

1. A fence slat comprising:
an elongated slat body having a front side wall, a back side wall, bottom side wall, top side wall, right side wall and left side wall;
first and second fasteners coupled to the right and left side walls of the elongated slat body and being configured to couple or interlock with adjacent slats; and
at least one chain-link interface coupler coupled to the back side wall to connect to a horizontal cross-bar of a chain-link fence.

2. The fence slat of claim 1, wherein the top side wall comprises a glass substrate and further comprising:
at least one photo-voltaic cell to convert sunlight to electricity under the glass substrate; and
electrical wire for coupling the electricity to the first and second fasteners.

3. The fence slat of claim 1, wherein the top side wall comprises a glass substrate and further comprising:
at least one photo-voltaic cell to convert sunlight to electricity under the glass substrate; and
a battery source coupled to the at least one photovoltaic cell to store the electricity; and
an illumination device coupled to the battery and to the elongated slat body.

4. The fence slat of claim 1, wherein a portion of the elongated slat body has affixed thereto a solar panel.

5. The fence slat of claim 1, further comprising a spike radiating from the bottom side wall, the spike configured to be received in earth.

6. The fence slat of claim 1, wherein the fence slat is constructed of: plastic, vinyl, polyvinyl chloride (PVC), synthetic material, man-made material, natural material or a combination thereof.

7. The fence slat of claim of claim 6, wherein one or more of the front side wall, the back side wall, the bottom side wall, the right side wall and the left side wall have a wood grain appearance.

8. The fence slat of claim 1, wherein the fence slat be 5, 6 or 7 feet tall.

9. A fence slat comprising:
an elongated slat body having a front side, a back side, bottom side, top side, right side and left side;
first and second fasteners coupled to the right and left sides of the elongated slat body and being configured to couple or interlock with adjacent slats;
at least one interface coupler coupled to the back side wall to connect to a horizontal support cross-bar; and
a solar panel coupled and integrated with at least one surface of the elongated slat body.

10. The fence slat of claim 9, wherein the solar panel comprises:
a glass substrate;
at least one photo-voltaic cell to convert sunlight to electricity under the glass substrate; and
electrical wire for coupling the electricity to the first and second fasteners.

11. The fence slat of claim 9, wherein the solar panel comprises:
a glass substrate; and
at least one photo-voltaic cell to convert sunlight to electricity under the glass substrate; and
further comprising:
a battery source coupled to the at least one photovoltaic cell to store the electricity; and
an illumination device coupled to the battery and to the elongated slat body.

12. The fence slat of claim 9, wherein a portion of the elongated slat body has affixed thereto a solar panel.

13. The fence slat of claim 9, further comprising a spike radiating from the bottom side, the spike configured to be received in earth.

14. The fence slat of claim 9, wherein the fence slat is constructed of:
plastic,
vinyl,
polyvinyl chloride (PVC),
synthetic material,
man-made material,
natural material or
a combination of synthetic and natural materials.

15. The fence slat of claim of claim 14, wherein one or more of the front side, the back side, the bottom side, the right side and the left side have a wood grain appearance.

16. A modular fence system comprising:
a plurality of fence slats configured to be interlocked or interconnected together to form a privacy fence, the plurality of fence slats comprises one or more of a solar-fence slat and a non-solar fence slat.

17. The fence system of claim 16, wherein each fence slat comprises:
an elongated slat body having a front side, a back side, bottom side, top side, right side and left side;
first and second fasteners coupled to the right and left sides of the elongated slat body and being configured to couple or interlock with adjacent slats;
at least one interface coupler coupled to the back side wall to connect to a horizontal support cross-bar and
wherein the solar fence slat further includes:
a solar panel coupled and integrated with at least one surface of the elongated slat body to convert sunlight to electricity.

18. The fence system of claim 17, wherein the solar panel comprises:
a glass substrate;
at least one photo-voltaic cell to convert the sunlight to the electricity under the glass substrate; and
electrical wire for coupling the electricity to the first and second fasteners.

19. The fence slat of claim 17, further comprising:
a battery source coupled to the solar panel to store the electricity; and
an illumination device coupled to the battery and to the elongated slat body.

20. The fence slat of claim 17, further comprising a spike radiating from the bottom side, the spike configured to be received in earth and the horizontal support cross bar is part of an existing chain-link fence system.
